(19) United States
(12) Patent Application Publication
(10) Pub. No.: US 2008/0298921 A1
(43) Pub. Date: Dec. 4, 2008

(54) COATED CUTTING TOOL INSERT

(75) Inventors: Rickard SUNDSTROM, Alta (SE); Alexandra Kusoffsky, Lidingo (SE); Marie Pettersson, Alvsjo (SE); Anders Lundqvist, Haninge (SE)

Correspondence Address: DRINKER BIDDLE & REATH (DC), 1500 K STREET, N.W., SUITE 1100, WASHINGTON, DC, 20005-1209, US

(73) Assignee: Sandvik Intellectual Property AB, Sandviken (SE)

(21) Appl. No.: 12/130,220

(22) Filed: May 30, 2008

(30) Foreign Application Priority Data
Jun. 1, 2007 (SE) 0701321-2

(51) Int. Cl. B23C 3/00; B32B 5/16; C23C 16/32

(52) U.S. Cl. 409/132; 428/336; 427/249.19

(57) ABSTRACT

A coated cutting tool insert is disclosed particularly useful for dry and wet machining, preferably milling, in un-, low- and high alloyed steels and cast iron, with or without raw surface zones. The insert is characterized by a WC—TaC—NbC—Co cemented carbide with a W alloyed Co-binder phase and a coating including an innermost layer of TiCₓN_{y}O_{z} with columnar grains and a top layer, at least on the rake face, of a smooth α-Al₂O₃.

### RELATED APPLICATIONS DATA

This application claims priority under 35 U.S.C. § 119 and/or § 365 to Swedish Application No. SE 0701321-2, filed Jun. 1, 2008, the entire contents of which are incorporated herein by reference.

### FIELD

The present disclosure relates to a coated cemented carbide cutting tool insert particularly useful for dry and wet machining, preferably milling, of un-, low- and highly alloyed steels and cast irons, with raw surfaces such as cast skin, forged skin, hot or cold rolled skin, or premachined surfaces.

### BACKGROUND

In the discussion of the background that follows, reference is made to certain structures and/or methods. However, the following references should not be construed as an admission that these structures and/or methods constitute prior art. Applicant expressly reserves the right to demonstrate that such structures and/or methods do not qualify as prior art.

When machining, the cemented carbide cutting edge will be subjected to wear. The wear can be characterised by different mechanisms, such as chemical wear, abrasive wear, adhesive wear and edge chipping caused by cracks formed along the cutting edge, the so called comb cracks. Under severe cutting conditions bulk and edge line breakages commonly occur. Depending on the work piece materials and cutting conditions, different properties of the cutting insert are required. For example, when cutting steel components with raw surface zones or cutting under other difficult conditions, the coated cemented carbide insert must be based on a tough carbide substrate and have a coating with excellent adhesion. When machining low alloyed steels and cast irons using high cutting speed and large radial depth of cut, the chemical wear is generally the dominating wear type. Here, generally 7 to 14 μm thick CVD-coatings are preferred.

Measures can be taken to improve or optimize cutting performance with respect to a specific wear type. However, very often such measures will have a negative effect on other wear properties. The influence of some possible measures is given below:

1) Comb crack formation can be reduced by lowering the binder phase content. However, low binder content will lower the toughness properties of the cutting inserts which is far from desirable.

2) Improved chemical wear can be obtained by increasing the coating thickness. However, thick coatings increase the risk for flaking and will also lower the resistance to adhesive wear.

3) Machining at high cutting speeds and at other conditions leading to high cutting edge temperatures require a cemented carbide with higher amounts of cubic carbides (solid solution of WC—TiC—TaC—NbC), but such carbides will promote comb crack formation.

4) Improved toughness can be obtained by increasing the cobalt binder content. However, high cobalt content decreases the resistance to plastic deformation.

Commercial cemented carbide grades are typically positioned and optimized with respect to one or a few of the mentioned wear types and hence to a specific cutting application area.

U.S. Pat. No. 6,062,776 discloses a coated cutting tool insert particularly useful for milling in low and medium alloyed steel with or without raw surface zones during wet or dry conditions. The insert is characterized by WC—Co cemented carbide with a low content of cubic carbides and a highly W-alloyed binder phase, a coating including an innermost layer of TiCₓN_{y}O_{z} with columnar grains and a layer of κ-Al₂O₃ with a top layer of TiN.

U.S. Pat. No. 6,406,224 discloses a coated cutting tool insert also particularly useful for milling of alloyed steel with or without abrasive surface zones at high cutting speeds. The coated cutting tool insert consists of a cemented carbide body with a composition of 7.1-7.9 wt % Co, 0.2-1.8 wt % cubic carbides of the metals Ta, Nb and Ti and balance WC. The insert is coated with an innermost layer of TiCₓN_{y}O_{z} with columnar grains and a layer of κ-Al₂O₃ with a top layer of TiN.

EP-A-736615 discloses a coated cutting insert particularly useful for dry milling of grey cast iron. The insert is characterized by having a straight WC—Co cemented carbide substrate and a coating consisting of a layer of TiCₓN_{y}O_{z} with columnar grains and a top layer of fine grained textured α-Al₂O₃.

EP-A-1696051 discloses a coated cutting tool insert suitable for machining of metals by turning, milling, drilling or by similar chip forming machining methods. The tool insert is particularly useful for interrupted toughness demanding cutting operations.

U.S. Pat. No. 6,200,671 disclose a coated turning insert particularly useful for turning in stainless steel. The insert is characterised by WC—Co-based cemented carbide substrate having a highly W-alloyed Co-binder phase and a coating including an innermost layer of TiCₓN_{y}O_{z} with columnar grains and a top layer of TiN and an inner layer of fine grained κ-Al₂O₃.

### SUMMARY

The inventors have developed an improved cutting tool insert, preferably for milling. The combined features are: a specific cemented carbide composition, a certain WC grain size, alloyed binder phase, an inner coating consisting of a number of defined layers and a smooth top rake face layer of α-Al₂O₃.

The insert has improved cutting performance in un-, low- and highly alloyed steel, with or without raw surface zones preferably under stable conditions in both dry and wet machining. The disclosed cutting tool insert also works well in cast irons. The cutting tool shows improved cutting properties compared to prior art inserts with respect to many of the wear types earlier mentioned. In particular, chemical resistance and comb crack resistance have been improved.

An exemplary cutting tool milling insert for machining of unalloyed, low and high alloyed steels and cast irons, with or without raw surfaces, during wet or dry conditions comprises a cemented carbide body, and a coating at least partly covering the body, wherein said cemented carbide body has a composition of 8.1 to 9.3 wt % Co, 1.00 to 1.45 wt % TaC, 0.10 to 0.50 wt % NbC and balance WC, wherein a coercivity is in the range 14.9 to 16.7 kA/m, and a CW-ratio is 0.80 to <1.00, wherein said coating is 7.5 to 13.5 μm thick and includes at least three layers of TiCₓN_{y}O_{z} with a total thickness of 3.0 to 8.0 μm, the TiCₓN_{y}O_{z} layers including a first TiCₓN_{y}O_{z} layer adjacent to the cemented carbide body having a composition of x+y=1, x>=0, a second TiCₓN_{y}O_{z} layer having a composition of x>0.4, y>0.4 and 0=<z<0.1, a third TiCₓN_{y}O_{z} bonding layer with needle shaped grains adjacent to an α-Al₂O₃-layer having a composition of x+y+z>=1 and z>0, and wherein the α-Al₂O₃-layer is an outer layer at least on a rake face, the α-Al₂O₃-layer has a thickness of 2.0 to 6.0 μm, and at least a portion of the α-Al₂O₃-layer is blasted smooth with flattened grains on surfaces that have been subjected to the blasting treatment.

An exemplary method of making a cutting insert including a cemented carbide body and a coating comprises forming the cemented carbide body by a powder metallurgical technique including wet milling of powders forming hard constituents and binder phase, compacting the milled mixture to bodies of desired shape and size, and sintering the compacted bodies, wherein said cemented carbide body has a composition of 8.1 to 9.3 wt % Co, 1.00 to 1.45 wt % TaC, 0.10 to 0.50 wt % NbC, and balance WC, a coercivity in the range 14.9 to 16.7 kA/m, and a CW-ratio of 0.80 to <1.00, coating at least a portion of the cemented carbide body with a 7.5 to 13.5 μm thick coating, wherein the coating including an inner coating having at least three layers of TiCₓN_{y}O_{z} and an outer layer having a smooth α-Al₂O₃-layer at least on a rake face of the cutting insert, wherein the TiCₓN_{y}O_{z}-layers have a total thickness of 3.0 to 8.0 μm, wherein the coating comprises a first TiCₓN_{y}O_{z} layer adjacent to the cemented carbide having a composition of x+y=1, x>=0, deposited by a CVD method using a reaction mixture consisting of TiCl₄, H₂ and N₂, a second TiCₓN_{y}O_{z} layer having a composition of x>0.4, y>0.4 and 0=<z<0.1, deposited by a MTCVD-technique at a temperature of 885 to 850° C. and with CH₃CN as the carbon/nitrogen source, a third TiCₓN_{y}O_{z} bonding layer with needle shaped grains having a composition of x+y+z>=1 and z>0, deposited by a CVD method using a reaction mixture consisting of TiCl₄, H₂ and N₂, the third TiCₓN_{y}O_{z} bonding layer adjacent to the α-Al₂O₃-layer, and wherein the α-Al₂O₃-layer has a thickness of 2.0 to 6.0 μm deposited by a CVD-technique, and subjecting the insert to a blasting treatment at least on the rake face so that a smooth α-Al₂O₃ with flattened grains is exposed.

A method of machining a workpiece with the cutting insert is also disclosed, where the method is one of milling with a 90° entering angle, face milling with a 45° to 75° entering angle, and high feed and round insert milling.

It is to be understood that both the foregoing general description and the following detailed description are exemplary and explanatory and are intended to provide further explanation of the invention as claimed.

### BRIEF DESCRIPTION OF THE DRAWING

The following detailed description can be read in connection with the accompanying drawings in which like numerals designate like elements and in which:

FIG. 1 shows a light optical micrograph in 50× magnification of the crater wear pattern of a sample insert.

FIG. 2 shows a light optical micrograph in 50× magnification of an insert according to prior art, when subjected to face milling test.

FIG. 3 shows a light optical micrograph in 50× magnification of the difference in edge line toughness of a sample insert.

FIG. 4 shows a light optical micrograph in 50× magnification of an insert according to prior art, when subjected to a face milling test.

### DETAILED DESCRIPTION

Exemplary embodiments of a cutting tool insert comprises a cemented carbide body with a W alloyed Co-binder phase, a well balanced chemical composition and a well selected grain size of the WC, and a coating consisting of a columnar TiCₓN_{y}O_{z}-inner layer followed by a smooth α-Al₂O₃-top layer. A TiN-layer is preferably the top layer at the clearance faces of the insert.

According to the present disclosure, a coated cutting tool insert is provided comprising a cemented carbide body with a composition of 8.1 to 9.3 wt % Co, preferably 8.3 to 9.1 wt % Co, most preferably 8.4 to 9.0 wt % Co, and 1.00 to 1.45 wt % TaC, preferably 1.18 to 1.28 wt % TaC, and 0.10 to 0.50 wt % NbC, preferably 0.25 to 0.35 wt % NbC, and balance WC. The cemented carbide body may also contain smaller amounts of other elements, but then at a level corresponding to a technical impurity. The coercivity is in the range 14.9 to 16.7 kA/m, preferably 15.3 to 16.3 kA/m.

The cobalt binder phase is alloyed with a certain amount of W giving the disclosed cemented carbide cutting insert its desired properties. W in the binder phase influences the magnetic properties of cobalt and can hence be related to a value CW-ratio, defined as

CW-ratio=magnetic-% Co/wt-% Co

where magnetic-% Co is the weight percentage of magnetic Co and wt-% Co is the weight percentage of Co in the cemented carbide.

The CW-ratio varies between 1 and about 0.75 dependent on the degree of alloying. A lower CW-ratio corresponds to higher W contents and CW-ratio=1 corresponds practically to an absence of W in the binder phase.

It has been found that improved cutting performance is achieved if the cemented carbide has a CW-ratio of 0.80 to <1.00, preferably 0.81 to 0.90, most preferably 0.82 to 0.88.

The cemented carbide may also contain small amounts, <1 volume %, of η-phase (M₆C), without any detrimental effects. From the specified CW-ratios (<1), it also follows that no free graphite is allowed in the disclosed cemented carbide body.

The cemented carbide insert is at least partly coated with a 7.5 to 13.5 μm thick coating including at least three layers of TiCₓN_{y}O_{z}. The three layers form an inner coating with an α-Al₂O₃-layer as the outer layer at least on the rake face. The TiCₓN_{y}O_{z}-layers, having a total thickness of 3.0 to 8.0 μm, comprise:
a first TiCₓN_{y}O_{z} layer adjacent to the cemented carbide having a composition of x+y=1, x>=0, preferably x<0.2 and z=0;
a second TiCₓN_{y}O_{z} layer having a composition of x>0.4, y>0.4 and 0=<z<0.1, preferably z=0; and
a third TiCₓN_{y}O_{z} bonding layer with needle shaped grains adjacent to the α-Al₂O₃-layer having a composition of x+y+z>=1 and z>0, preferably z>0.2 and x+y+z=1.

The outer α-Al₂O₃-layer has a thickness of 2.0 to 6.0 μm with flattened grains on the surfaces that have been subjected to a blasting treatment.

In one embodiment, an additional 0.1 to 2.3 μm, preferably 0.1 to 1 μm, coloured layer is present on top of the α-Al₂O₃-layer preferably of TiN, Ti(C,N), TiC, ZrN or HfN.

The present disclosure also relates to a method of making a coated cutting tool insert by powder metallurgical technique, wet milling of powders forming hard constituents and binder phase, compacting the milled mixture to bodies of desired shape and size and sintering, comprising a cemented carbide body with a composition of 8.1 to 9.3 wt % Co, preferably 8.3 to 9.1 wt % Co, most preferably 8.4 to 9.0 wt % Co, and 1.00 to 1.45 wt % TaC, preferably 1.18 to 1.28 wt % TaC, and 0.10 to 0.50 wt % NbC, preferably 0.25 to 0.35 wt % NbC, and balance WC. The cemented carbide body may also contain smaller amounts of other elements, but then on a level corresponding to a technical impurity. The milling and sintering conditions are chosen to obtain an as-sintered structure with the coercivity in the range 14.9 to 16.7 kA/m, preferably within 15.3 to 16.3 kA/m, and a CW-ratio of 0.80 to <1.00, preferably 0.81 to 0.90, most preferably 0.82 to 0.88.

The cemented carbide insert body is at least partly coated with a 7.5 to 13.5 μm thick coating including at least three layers of TiCₓN_{y}O_{z} forming an inner coating with a blasted α-Al₂O₃-layer as the outer layer at least on the rake face. The TiCₓN_{y}O_{z}-layers, having a total thickness of 3.0 to 8.0 μm, comprise:
a first TiCₓN_{y}O_{z} layer adjacent to the cemented carbide having a composition of x+y=1, x>=0, preferably x<0.2 and z=0 using known CVD method using a reaction mixture consisting of TiCl₄, H₂ and N₂;
a second TiCₓN_{y}O_{z} layer having a composition of x>0.4, y>0.4 and 0=<z<0.1, preferably z=0, by using the well-known MTCVD-technique, temperature 885 to 850° C. and CH₃CN as the carbon/nitrogen source and optionally CO and/or CO₂; and
a third TiCₓN_{y}O_{z} bonding layer with needle shaped grains adjacent to the α-Al₂O₃-layer having a composition of x+y+z>=1 and z>0, preferably z>0.2 and x+y+z=1 using known CVD method using a reaction mixture consisting of TiCl₄, H₂, CO and/or CO₂ and optionally N₂,

The α-Al₂O₃-layer with a thickness of 2.0 to 6.0 μm is deposited by using known CVD-technique and subjecting the insert to a blasting treatment at least on the rake face.

In one embodiment, an additional 0.1 to 2.3 μm, preferably 0.1 to 1 μm, coloured layer is deposited on top of the α-Al₂O₃-layer preferably of TiN, Ti(C,N), TiC, ZrN or HfN preferably using CVD technique prior to the blasting treatment.

The present disclosure also relates to the use of an insert according to above for dry and wet machining, preferably milling, of unalloyed, low and high alloyed steels and cast irons, with raw surfaces such as cast skin, forged skin, hot or cold rolled skin or pre-machined surfaces at cutting speeds and feed rates according to the following:

Milling with 90° Entering Angle:

Cutting speed: 25 to 400 m/min, preferably 150 to 300 m/min and feed rate: 0.04 to 0.4 mm/tooth;

Face Milling (45-75° Entering Angle):

Cutting speed: 25 to 600 m/min, preferably 200 to 400 m/min and feed rate: 0.05 to 0.7 mm/tooth;

High Feed and Round Insert Milling Concepts:

Cutting speed: 25 to 600 m/min and feed rate: 0.05 to 3.0 mm/tooth, preferably 0.3 to 1.8 mm/tooth.

### EXAMPLE 1

### Invention A

Cemented carbide milling inserts in the following styles R390-11T308M-PM, R390-170408M-PM, R245-12T3M-PM, R300-1648M-PH and R300-1240M-PH having a composition of 8.7 wt-% Co, 1.25 wt-% TaC, 0.28 wt-% NbC and balance WC and with a coercivity of 15.5 kA/m, corresponding to a WC grain size of about 1.3 μm, and a CW-ratio of 0.84 as measured in the FORSTER KOERZIMAT CS 1.096 from Foerster Instruments Inc. were prepared. The inserts were coated as follows:

a first layer of 0.5 μm TiCₓN_{y}O_{z} with a composition of about x=0.05, y=0.95 and z=0 using known CVD method using a reaction mixture consisting of TiCl₄, H₂ and N₂;

a second layer of 6 μm columnar TiCₓN_{y}O_{z} with a composition of about x=0.55, y=0.45 and z=0 by using the well-known MTCVD-technique, temperature 885-850° C. and CH₃CN as the carbon/nitrogen source; and

a third, bonding layer of 0.5 μm TiCₓN_{y}O_{z}. The grains of this third layer were needle shaped and the composition was about x=0.5, y=0 and z=0.5; and

a fourth layer consisting of 4 μm α-Al₂O₃ and finally a top layer of about 2 μm TiN was deposited by using known CVD-technique. XRD-measurements confirmed that the Al₂O₃-layer consisted to 100% of the α-phase.

After the coating cycle the top side (rake face) of the inserts was subjected to intense wet blasting with a slurry consisting of Al₂O₃ grits and water. The blasting treatment removed the top TiN-layer on the rake face exposing a smooth α-Al₂O₃ with most grains flattened.

### EXAMPLE 2

### Prior Art B

Cemented carbide milling inserts in the following styles R390-11T308M-PM, R390-170408M-PM, R245-12T3M-PM, R300-1648M-PH and R300-1240M-PH with a composition of 7.6 wt-% Co, 1.25 wt-% TaC, 0.28 wt-% NbC and balance WC and with a coercivity of 14.7 kA/m, corresponding to a WC grain size of about 1.5 μm, and a CW ratio of 0.91 as measured in the FORSTER KOERZIMAT CS 1.096 from Foerster Instruments Inc. were produced. The inserts were coated as follows: a first layer of 0.5 μm equiaxed TiCₓN_{y}-layer (with a high nitrogen content corresponding to an estimated x=0.95 and y=0.05) followed by a 4 μm thick Ti(C,N)-layer, with columnar grains by using MTCVD-technique at a temperature 885 to 850° C. and with CH₃CN as the carbon/nitrogen source. In subsequent steps during the same coating cycle, a 1.0 μm thick layer of Al₂O₃ was deposited using a temperature 970° C. and a concentration of H₂S dopant of 0.4% as disclosed in EP-A-523 021. A thin, 0.5 μm, layer of TiN was deposited on top according to known CVD-technique. XRD-measurement showed that the Al₂O₃-layer consisted of 100% κ-phase.

### EXAMPLE 3

Inserts of the different styles from Examples 1 and 2 were compared in cutting tests.

Operation 1: Face Milling, Coromill 245

| Work-piece: | Plate | |
|---|---|---|
| Material: | Unalloyed steel, 200HB | |
| Cutting speed: | 350 | m/min |
| Feed rate/tooth: | 0.45 | mm/tooth |
| Axial depth of cut: | 2.0 | mm |
| Radial depth of cut: | 95 | mm |
| Insert-style: | R245-12T3M-PH | |
| Cutter diameter: | 250 | mm |

Note: One insert in the cutter, dry machining.

Tool-life criterion was flank wear and chemical wear. A combination of better wear resistance and better resistance to chemical wear gave a considerable increase in tool life.

| Results: | Tool-life, minutes in cut |
|---|---|
| Invention A: | 36 |
| Prior art B: | 19 |

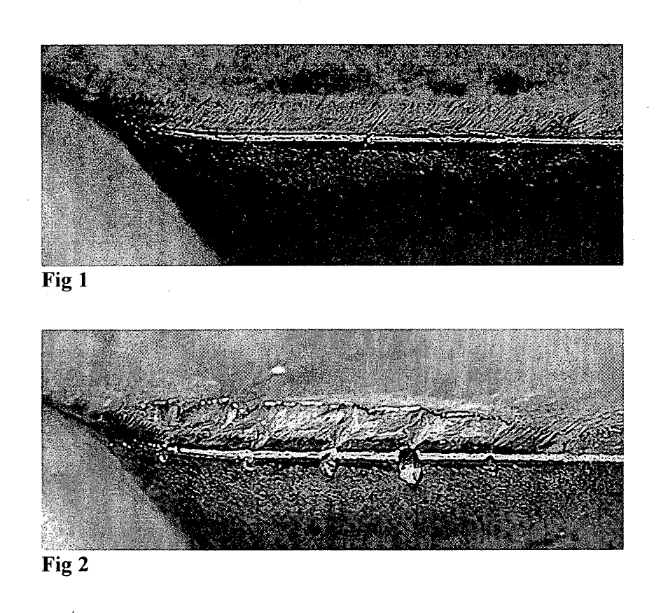

The improved resistance to chemical wear is clearly shown for the present invention A in FIG. 1 compared to prior art B in FIG. 2. The edge line is intact in the present invention FIG. 1 whereas in the prior art B, FIG. 2, a crater with comb cracks has developed.

Operation 2: Face Milling, Coromill 245

| Work-piece: | Plate | |
|---|---|---|
| Material: | Unalloyed steel, 200HB | |
| Cutting speed: | 300 | m/min |
| Feed rate/tooth: | 0.35 | mm/tooth |
| Axial depth of cut: | 1.0-3.5 | mm |
| Radial depth of cut: | 120 | mm |
| Insert-style: | R245-12T3M-PH | |
| Cutter diameter: | 160 | mm |

Note: Ten inserts in the cutter, dry machining.

Tool-life criterion was flank wear and edge line toughness. A combination of better wear resistance and better edge line toughness gave a considerable increase in tool life.

| Results: | Tool-life: minutes in cut |
|---|---|
| Invention A: | 70 |
| Prior art B: | 31 |

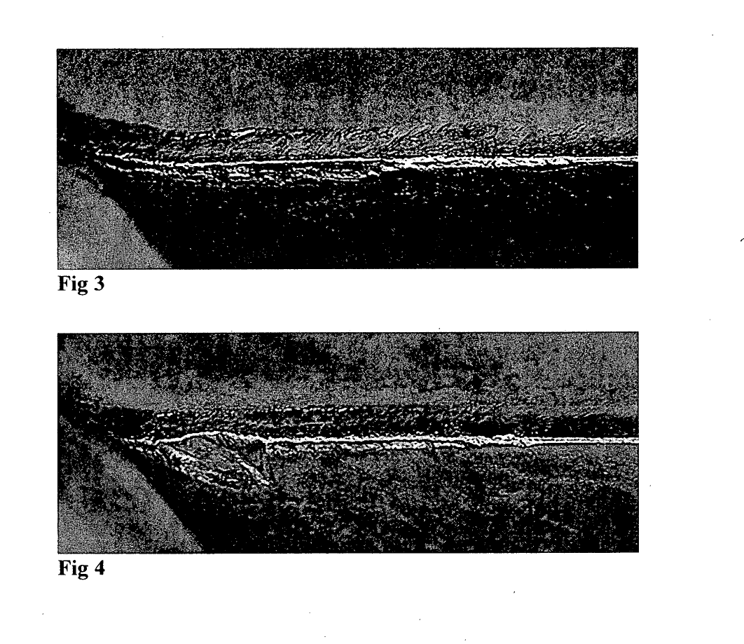

The improved edge line toughness is clearly shown for the present invention A in FIG. 3 compared to prior art B in FIG. 4. The edge line is intact in the present invention A, FIG. 3 whereas in the prior art B, FIG. 4, comb cracks have developed resulting in edge line breakage.

Operation 3: Face Milling, Coromill 210

| Work-piece: | Plate | |
|---|---|---|
| Material: | High-alloyed steel, 240HB | |
| Cutting speed: | 142 | m/min |
| Feed rate/tooth: | 1.33 | mm/tooth |
| Axial depth of cut: | 1.5 | mm |
| Radial depth of cut: | 76 | mm |
| Insert-style: | R210-140512M-PM | |
| Cutter diameter: | 100 | mm |

Note: Seven inserts in the cutter, dry machining.

Tool-life criterion was flank wear. A combination of better abrasive wear resistance gave a considerable increase in tool life.

| Results: | Tool-life, minutes in cut |
|---|---|
| Invention A: | 90 |
| Prior art B: | 31 |

Operation 4: Face Milling, Coromill 245

| Work-piece: | Plate | |
|---|---|---|
| Material: | High-alloyed steel, 230HB | |
| Cutting speed: | 350 | m/min |
| Feed rate/tooth: | 0.40 | mm/tooth |
| Axial depth of cut: | 2.5 | mm |
| Radial depth of cut: | 170 | mm |
| Insert-style: | R245-12T3M-PH | |
| Cutter diameter: | 200 | mm |

Note: 12 inserts in the cutter, dry machining.

Edge line toughness, chipping behaviour on insert was the tool life criterion. A combination of better wear resistance and better edge line toughness gave a considerable increase in tool life.

| Results: | Tool-life: minutes in cut |
|---|---|
| Invention A: | 43 |
| Prior art B: | 17.2 |

Operation 5: Face Milling, Coromill 300

| Work-piece: | Main fitting | |
|---|---|---|
| Material: | High-alloyed steel, 330HB | |
| Cutting speed: | 263 | m/min |
| Feed rate/tooth: | 0.25 | mm/tooth |
| Axial depth of cut: | 1.5 | mm |
| Radial depth of cut: | 0-125 | mm |
| Insert-style: | R245-12T3M-PH | |
| Cutter diameter: | 125 | mm |

Note: Eight inserts in the cutter, dry machining.

Tool-life criterion edge line toughness chipping. A combination of better comb crack resistance and better edge line toughness gave a considerable increase in tool life.

| Results: | Tool-life, minutes in cut |
|---|---|
| Invention A: | 32 |
| Prior art B: | 21 |

Operations 1-5 in example 3 clearly show that the inserts from Example 1 outperform the prior art inserts according to Example 2.

Although described in connection with preferred embodiments thereof, it will be appreciated by those skilled in the art that additions, deletions, modifications, and substitutions not specifically described may be made without department from the spirit and scope of the invention as defined in the appended claims.

What is claimed is:

1. A cutting tool milling insert for machining of unalloyed, low and high alloyed steels and cast irons, with or without raw surfaces, during wet or dry conditions, the cutting tool milling insert comprising:
a cemented carbide body; and
a coating at least partly covering the body,
wherein said cemented carbide body has a composition of 8.1 to 9.3 wt % Co, 1.00 to 1.45 wt % TaC, 0.10 to 0.50 wt % NbC and balance WC,
wherein a coercivity is in the range 14.9 to 16.7 kA/m, and a CW-ratio is 0.80 to <1.00,
wherein said coating is 7.5 to 13.5 μm thick and includes at least three layers of TiCₓN_{y}O_{z} with a total thickness of 3.0 to 8.0 μm, the TiCₓN_{y}O_{z} layers including:
a first TiCₓN_{y}O_{z} layer adjacent to the cemented carbide body having a composition of x+y=1, x>=0,
a second TiCₓN_{y}O_{z} layer having a composition of x>0.4, y>0.4 and 0=<z<0.1,
a third TiCₓN_{y}O_{z} bonding layer with needle shaped grains adjacent to an α-Al₂O₃-layer having a composition of x+y+z>=1 and z>0, and
wherein the α-Al₂O₃-layer is an outer layer at least on a rake face, the α-Al₂O₃-layer has a thickness of 2.0 to 6.0 μm, and at least a portion of the α-Al₂O₃-layer is blasted smooth with flattened grains on surfaces that have been subjected to the blasting treatment.

2. The cutting insert according to claim 1, wherein the cemented carbide has the composition 8.3 to 9.1 wt-% Co, 1.18 to 1.28 wt % TaC, 0.25 to 0.35 wt % NbC and balance WC, with a coercivity within 15.3 to 16.3 kA/m and a CW-ratio of 0.8 to 0.90.

3. The cutting tool insert according to claim 1, wherein the coating includes a 0.1 to 2.3 μm coloured top layer at a flank face.

4. The cutting tool insert according to claim 3, wherein the coloured layer consists of TiN, Ti(C,N), TiC, ZrN and/or HfN deposited by CVD- or PVD-technique.

5. The cutting tool insert according to claim 4, wherein the coloured layer is deposited using CVD-technique.

6. The cutting tool insert according to claim 1, wherein the first TiCₓN_{y}O_{z} layer has a composition with x<0.2 and z=0, the second TiCₓN_{y}O_{z} layer has a composition with z=0, and the third TiCₓN_{y}O_{z} bonding layer has a composition with z>0.2 and x+y+z=1.

7. A method of making a cutting insert, the cutting insert including a cemented carbide body and a coating, the method comprising:
forming the cemented carbide body by a powder metallurgical technique including wet milling of powders forming hard constituents and binder phase, compacting the milled mixture to bodies of desired shape and size, and sintering the compacted bodies,
wherein said cemented carbide body has a composition of 8.1 to 9.3 wt % Co, 1.00 to 1.45 wt % TaC, 0.10 to 0.50 wt % NbC, and balance WC, a coercivity in the range 14.9 to 16.7 kA/m, and a CW-ratio of 0.80 to <1.00;
coating at least a portion of the cemented carbide body with a 7.5 to 13.5 μm thick coating,
wherein the coating including an inner coating having at least three layers of TiCₓN_{y}O_{z} and an outer layer having a smooth α-Al₂O₃-layer at least on a rake face of the cutting insert,
wherein the TiCₓN_{y}O_{z}-layers have a total thickness of 3.0 to 8.0 μm,
wherein the coating comprises:
a first TiCₓN_{y}O₇ layer adjacent to the cemented carbide having a composition of x+y=1, x>=0, deposited by a CVD method using a reaction mixture consisting of TiCl₄, H₂ and N₂,
a second TiCₓN_{y}O_{z} layer having a composition of x>0.4, y>0.4 and 0=<z<0.1, deposited by a MTCVD-technique at a temperature of 885-850° C. and with CH₃CN as the carbon/nitrogen source,
a third TiCₓN_{y}O_{z} bonding layer with needle shaped grains having a composition of x+y+z>=1 and z>0, deposited by a CVD method using a reaction mixture consisting of TiCl₄, H₂ and N₂, the third TiCₓN_{y}O_{z} bonding layer adjacent to the α-Al₂O₃-layer, and
wherein the α-Al₂O₃-layer has a thickness of 2.0 to 6.0 μm deposited by a CVD-technique; and
subjecting the insert to a blasting treatment at least on the rake face so that a smooth α-Al₂O₃ with flattened grains is exposed.

8. The method according to claim 7, comprising depositing an additional 0.1 to 2.3 μm coloured layer on top of the α-Al₂O₃-layer

9. The method according to claim 8, wherein the coloured layer is TiN, Ti(C,N), TiC, ZrN or HfN.

10. The method according to claim 9, wherein the coloured layer is deposited by a CVD technique prior to the blasting treatment.

11. The method according to claim 7, comprising depositing, after the blasting treatment, an additional 0.1 to 2.3 μm coloured top layer at the flank faces.

12. The method according to claim 7, wherein the coloured top layer is TiN, Ti(C,N), TiC, ZrN or HfN.

13. The method according to claim 9, wherein the coloured layer is deposited by a CVD technique.

14. The method according to claim 7, wherein the cemented carbide body has a composition of 8.3 to 9.1 wt-% Co, 1.18 to 1.28 wt % TaC, 0.25 to 0.35 wt % NbC, and balance WC, with a coercivity within 15.3 to 16.3 kA/m and a CW-ratio of 0.81 to 0.90.

15. The method according to claim 7, wherein the first TiCₓN_{y}O_{z} layer has a composition with x<0.2 and z=0, the second TiCₓN_{y}O_{z} layer has a composition with z=0, and the third TiCₓN_{y}O_{z} bonding layer has a composition with z>0.2 and x+y+z=1.

16. The method according to claim 7, wherein the cutting insert is for machining of a workpiece formed from an unalloyed steel, a low alloyed steel, a high alloyed steels or a cast iron.

17. The method according to claim 7, wherein the workpiece has a raw surface.

18. A method of machining a workpiece with an insert according to claim 1, the method comprising:
milling with a 900 entering angle at a cutting speed of 25 to 400 m/min and a feed rate of 0.04 to 0.4 mm/tooth,
wherein the workpiece is formed from an unalloyed steel, a low alloyed steel, a high alloyed steels or a cast iron.

19. The method according to claim 18, wherein the cutting speed is 150 to 300 m/min.

20. The method according to claim 18, wherein the workpiece has a raw surface or a premachined surface.

21. The method according to claim 20, wherein the raw surface is a cast skin, a forged skin, a hot rolled skin or cold rolled skin.

22. A method of machining a workpiece with an insert according to claim 1, the method comprising:
face milling with a 45 to 750 entering angle at a cutting speed of 25 to 600 m/min and a feed rate of 0.05 to 0.7 mm/tooth,
wherein the workpiece is formed from an unalloyed steel, a low alloyed steel, a high alloyed steels or a cast iron.

23. The method according to claim 22, wherein the cutting speed is 200 to 400 m/min.

24. The method according to claim 22, wherein the workpiece has a raw surface or a premachined surface.

25. The method according to claim 24, wherein the raw surface is a cast skin, a forged skin, a hot rolled skin or cold rolled skin.

26. A method of machining a workpiece with an insert according to claim 1, the method comprising:
high feed and round insert milling at a cutting speed of 25 to 600 m/min and a feed rate of 0.05 to 3.0 mm/tooth,
wherein the workpiece is formed from an unalloyed steel, a low alloyed steel, a high alloyed steels or a cast iron.

27. The method according to claim 26, wherein the feed rate is 0.3 to 1.8 mm/tooth.

28. The method according to claim 26, wherein the workpiece has a raw surface or a premachined surface.

29. The method according to claim 28, wherein the raw surface is a cast skin, a forged skin, a hot rolled skin or cold rolled skin.
